(19) United States
(12) Patent Application Publication
(10) Pub. No.: US 2017/0233858 A9
(43) Pub. Date: Aug. 17, 2017

(54) DARK SURFACE FINISHES ON TITANIUM ALLOYS

(71) Applicant: Apple Inc., Cupertino, CA (US)

(72) Inventors: Brian S. Tryon, Los Gatos, CA (US); James A. Wright, Los Gatos, CA (US); Weiming Huang, Fremont, CA (US); Herng-Jeng Jou, San Jose, CA (US)

(21) Appl. No.: 15/273,314

(22) Filed: Sep. 22, 2016

Related U.S. Application Data
(60) Provisional application No. 62/234,303, filed on Sep. 29, 2015.

(51) Int. Cl. C22F 1/18; C23C 14/58; C23C 10/28; C23C 10/60; C22C 14/00; C23C 14/16

(52) U.S. Cl. CPC C22F 1/186; C22C 14/00; C23C 14/16; C23C 10/28; C23C 10/60; C23C 14/5806; C23C 14/5853

(57) ABSTRACT

The disclosure is directed to treated titanium alloys comprising a titanium substrate coated with an oxidized surface coating or an oxide-interdiffused titanium substrate. By creating an oxidized surface coating or oxide-interdiffused titanium substrate at the titanium substrate surface, the resulting treated titanium alloy has a dark color (e.g., grey to black).

### CROSS-REFERENCE TO RELATED PATENT APPLICATIONS

This patent application claims the benefit under 35 U.S.C. §119(e) of U.S. Patent Application No. 62/234,303, entitled “DARK SURFACE FINISHES ON TITANIUM ALLOYS,” filed on Sep. 29, 2015, which is incorporated herein by reference in its entirety.

### FIELD

The disclosure relates to titanium alloys with a dark surface finish and methods of producing titanium alloys with a dark surface finish.

### BACKGROUND

It is often desirable to form strong, cost-effective metallic surfaces with a dark grey or black color. Conventional dark metallic materials can be produced using pure zirconium, or zirconium alloys. Such materials are expensive, heavy, and difficult to machine.

Titanium alloys are strong, lower weight alloys. Titanium alloys can be surface finished by conventional methods such as anodizing or surface coating treatments. However, such conventional oxidized or anodized surfaces typically have an average thickness on the order of nanometers. Cosmetic finishing can be accomplished by physical vapor deposition (PVD) coating or plating to achieve a given color or finish. For example, dark parts can be made directly by applying a PVD chromium carbide coating on a steel or titanium substrate. However, there have been no efforts at preparing a native oxide on a compositionally modified titanium surface.

There is a need for alloys having the strength and cost-effectiveness of titanium, at a grey or black color, as described herein.

### SUMMARY

In one aspect, the disclosure is directed to a coated titanium alloy. The alloy has an oxidized coating disposed on a titanium substrate. The coating has a dark surface color. In various embodiments, the coating can have an average depth of at least one micron.

In another aspect, the disclosure is directed to a titanium alloy having a darkened surface. The alloy includes an oxide-interdiffused titanium substrate on at least one surface of the alloy. The oxide-interdiffused titanium substrate can have a dark surface color.

In another aspect, the disclosure is directed to a method of creating a dark surface on a titanium alloy. An oxidizable surface coating is deposited on the titanium alloy substrate. The surface coating is oxidized to provide a dark surface finish.

In another aspect, the disclosure is directed to a method of creating a dark surface finish on a titanium alloy. An oxidizable surface coating is deposited on the titanium alloy. The oxidizable coating is interdiffused into the titanium alloy to form a surface coating-interdiffused titanium substrate portion. The surface coating-interdiffused titanium alloy portion is then oxidized to form an oxide-interdiffused titanium alloy having a dark color.

In some embodiments, the oxidizable surface coating may be deposited on the titanium alloy substrate using physical vapor deposition (PVD).

In some embodiments, the oxidizable surface coating may comprise zirconium.

In some embodiments, the surface coating may be heat treated under vacuum to interdiffuse the oxidizable coating into the titanium alloy, prior to oxidation.

In certain embodiments, oxidation is performed by heat treatment in air. In other embodiments, oxidation is performed in a pressure controlled environment, e.g., under vacuum or oxygen partial pressure.

In various aspects described herein, a native oxide is formed on a titanium surface. In certain embodiments, the titanium surface is compositionally modified. In various aspects, the average thickness of the oxidized surface coating or oxide-interdiffused portion of the alloy can be on the order of microns, e.g., up to 1 micron, up to 2 microns, up to 3 microns, up to 4 microns, up to 5 microns, etc.

Additional embodiments and features are set forth in part in the description that follows, and will become apparent to those skilled in the art upon reading of the specification. A further understanding of the nature and advantages of the present disclosure can be realized by reference to the remaining portions of the specification and the drawings, which forms a part of this disclosure.

### BRIEF DESCRIPTION OF THE DRAWINGS

Although the following figures and description illustrate specific embodiments and examples, the skilled artisan will appreciate that various changes and modifications may be made without departing from the spirit and scope of the disclosure.

FIG. 1 depicts a flow chart depicting methods of depositing an oxidizable surface coating onto a titanium substrate, optionally interdiffusing the coating, and oxidizing the coating or interdiffusing and oxidizing the coating, optionally simultaneously, to form a dark color.

FIG. 2 depicts an exemplary portable electronic device.

FIG. 3 depicts a coating deposited on a titanium substrate.

FIG. 4A depicts Zr deposited on the surface of Ti-6Al-4V.

FIG. 4B depicts Zr deposited on the surface of Ti-15V-3Al-3Cr-3Sn.

FIG. 5 depicts three different coating compositions.

FIG. 6 depicts five different coating compositions on a Ti-6-4 alloy.

FIG. 7A depicts oxidation of Zr705 used as a surface coating and oxidized by heat treatment at different temperatures and times.

FIG. 7B depicts a cross-section of Zr705 used as a surface coating and oxidized by heat treatment at 600° C.

FIG. 7C depicts a cross-section of an oxidized Zr705 used as a surface coating and oxidized by heat treatment at 700° C.

FIG. 8 depicts three calculated isothermal sections (in wt %) of the Nb—Ti—Zr phase diagram at 400° C., 570° C., and 700° C. using the thermodynamic description of Tokunaga et al., which are in agreement with experimentally determined.

### DETAILED DESCRIPTION

Reference will now be made in detail to representative embodiments described herein and illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The disclosure is directed to treated titanium alloys comprising a titanium substrate coated with an oxidized surface coating or an oxide-interdiffused titanium substrate, and related methods. Titanium alloys have high tensile strength and toughness. By creating an oxidized surface coating (i.e., native oxide) or oxide-interdiffused coating at the titanium substrate surface, the resulting treated titanium alloy may have a dark color (e.g., grey to black).

In various embodiments, the oxidized coated titanium substrate or oxide-interdiffused coated titanium substrate has a grey to black color. In some variations, the oxidized coated titanium alloy can have an interdiffused portion of unoxidized surface coating (otherwise as described herein).

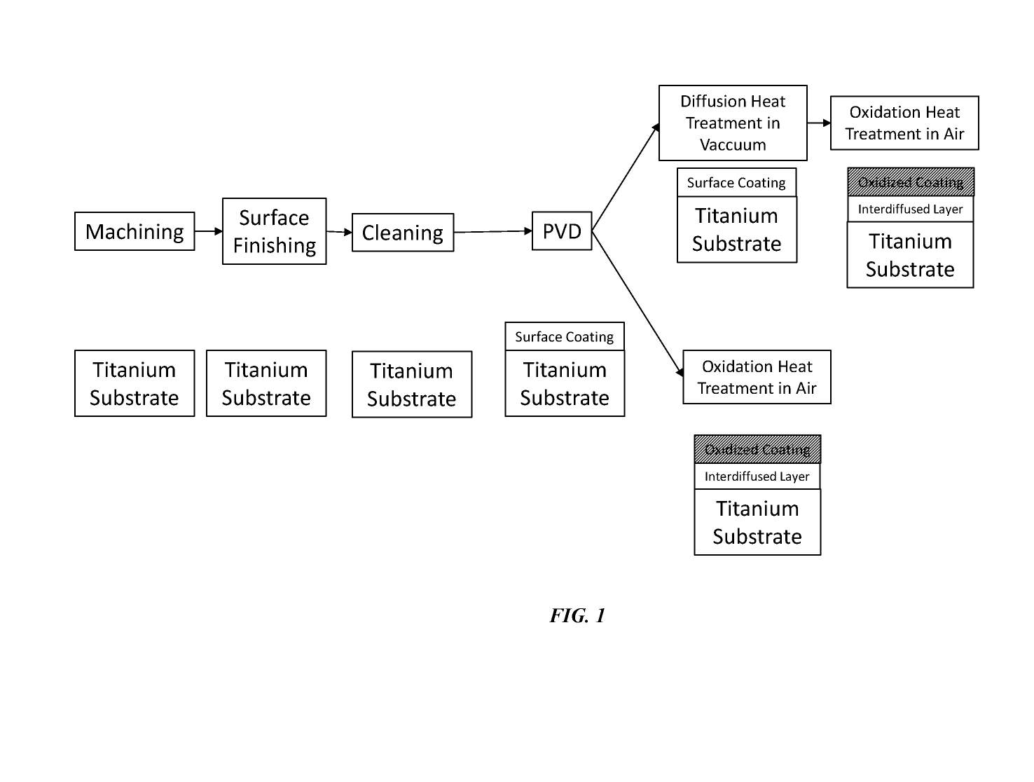

In one aspect, methods for creating a dark surface on a titanium alloy are provided. With reference to FIG. 1, a titanium alloy may be prepared, e.g., a titanium alloy may be machined to a desired form, optionally surfaced finished, and cleaned. An oxidizable surface coating is deposited on the titanium substrate, and then oxidized by heat treatment. In certain embodiments, the oxidizable surface coating may be oxidized in air or under a pressure controlled environment. In certain embodiments, the oxidizable surface coating may be heat treated in a pressure controlled environment, e.g., under vacuum, to interdiffuse the oxidizable coating into the titanium alloy, prior to oxidation. In certain embodiments, the oxidizable surface coating may interdiffuse into the titanium alloy during oxidation. The resulting oxidized coated titanium alloy may have a dark color or hue.

The titanium alloy can be titanium metal, or any titanium alloy known in the art. Examples of such titanium alloys include near-a titanium alloys, α+β titanium alloys (e.g. Ti 6Al-4V), and (β-titanium alloys (e.g., Ti-15V-3-3-3).

Near-αtitanium alloys are typically alloyed with 1-2% of (3 phase stabilizers, such as molybdenum, silicon or vanadium. Examples include Ti-6Al-2Sn-4Zr-2Mo, and Ti-5Al-5Sn-2Zr-2Mo. α+βtitanium alloys generally include some combination of both α and β stabilizers. Examples include Ti-6Al-4V, Ti-6Al-2Sn-4Zr-6Mo, and Ti-6Al-6V-2Sn. β and near β alloys contain sufficient beta stabilizers (such as molybdenum, silicon and vanadium) to allow them to maintain the beta phase when quenched. Examples include Ti-15V-3Cr-3Sn-3Al, Ti-10V-2Fe-3Al, Ti-13V-11Cr-3Al, and Ti-8Mo-8V-2Fe-3Al.

Oxidizable surface coatings can be any suitable surface coating that adheres to titanium metals that is capable of oxidizing under standard conditions, e.g., thermal oxidation. In certain aspects, the oxidizable surface coatings can be nominally pure metal or metal alloys, e.g., selected for thermodynamic stability. The relative percentage of alloy components can be selected by determining the thermodynamically stable phase for the alloy components. For example, in certain embodiments, the thermodynamic modelling of the Ti—Nb—Zr ternary system by Tokunaga et al., Materials Transactions, Vol. 48, No. 2 (2007) pp. 89-96, may be used to calculate the equilibrium phase relations at different temperatures. After a ternary alloy composition is determined for the homogenous phase, optional additional elements such as vanadium, hafnium, chromium, tantalum, and/or molybdenum can be added to the composition.

In various embodiments, the oxidizable surface coatings can include titanium, zirconium, niobium, vanadium, hafnium, tantalum, and alloys and combinations thereof. In certain variations, each element can be in an amount up to 10 w/w % of the total surface coating. In certain variations, the surface coating is zirconium or a zirconium alloy. Zirconium and zirconium alloys can form a black or dark oxide layer at temperatures between approximately 550° C. and 700° C. In certain further variations, zirconium provides a black or dark oxide layer at higher temperatures under controlled atmospheric conditions.

In certain embodiment, the oxidizable surface coating can be an unalloyed zirconium, or zirconium alloyed with titanium, niobium, or titanium and niobium, such as 50/50 Ti/Zr alloy (wt %), 55/34/11 TI/Zr/Nb (wt %); 57/31/12 Ti/Zr/Nb (wt %); 77/23 Zr/Nb (wt %), or Zr705 (zirconium alloy with 2-3% niobium content). In other embodiments, the oxidizable surface coating may comprise one or more oxidizable surface coating, e.g., deposited in one or more layers. For instance, the oxidizable surface coating may comprise one or more layers of oxidizable surface coatings. The one or more layers of oxidizable surface coatings can include titanium, zirconium, niobium, vanadium, hafnium, tantalum, and alloys and combinations thereof, as described above. In particular embodiments, the one or more layers of oxidizable surface coatings may comprise unalloyed zirconium, or zirconium alloy with titanium, niobium, or titanium and niobium content, such as 50/50 Ti/Zr alloy (wt %), 55/34/11 TI/Zr/Nb (wt %); 57/31/12 Ti/Zr/Nb (wt %); 77/23 Zr/Nb (wt %), or Zr705 (zirconium alloy with 2-3% niobium content).

In some embodiments, the alloy substrate and coating materials can include a small amount of impurities. The impurity elements can be intentionally added to modify the properties of the composition, such as improving the mechanical properties (e.g., hardness, strength, fracture mechanism, etc.) and/or improving the corrosion resistance. Alternatively, the impurities can be present as inevitable, incidental impurities, such as those obtained as a byproduct of processing and manufacturing. The impurities can be less than or equal to about 10 wt %, about 5 wt %, about 2 wt %, about 1 wt %, about 0.5 wt %, or about 0.1 wt %. In some embodiments, these percentages can be volume percentages instead of weight percentages.

Any method known in the art can be used to deposit the oxidizable surface coating onto the titanium alloy substrate. In one aspect, the oxidizable surface coating is deposited by physical vapor deposition (PVD), including cathodic arc deposition, electron beam physical vapor deposition, evaporative deposition, pulsed laser deposition, sputter deposition. Other deposition methods can include, but are not limited to ion vapor deposition (IVD), thermal spray, plasma spray, high velocity oxy-fuel (HVOF) coating, plating, or electroplating from an ionic liquid electrolyte bath.

As recognized by one of skill in the art, the deposition and thickness of the oxide can be varied by altering the time of deposition, temperature, composition, available oxygen, and surface area. The oxygen content of the oxidized surface coating can be varied by controlling the temperature of the deposition process. Alternatively, the partial pressure of oxygen can be varied to control the concentration of oxygen in the oxidized surface coating. The oxidation can be varied depending on the oxygen content. As described herein, the environment may be controlled to regulate the amount of oxygen controlling the vacuum pressure, and/or by controlling the amount of nitrogen and/or argon.

In certain variations, the oxidizable surface coating may be deposited to an average thickness of greater than about 0.5 microns. In some variations, the average thickness of the oxidizable surface coating is less than 1 micron. Alternatively, the average thickness of the oxidizable surface coating is less than 2 microns. In other variations, the average thickness of the oxidizable surface coating is less than 3 microns. In other variations, the average thickness of the oxidizable surface coating is less than 4 microns. In still other variations, the average thickness of the s oxidizable surface coating is less than 5 microns.

In another aspect, with further reference to FIG. 1, the oxidizable surface coating can interdiffuse into the titanium substrate, for example by heat treatment under pressure controlled environment to form an coating-interdiffused layer in the titanium substrate. In certain embodiments, the coating-interdiffused titanium substrate may then be oxidized, such as by oxidation in air or other methods known to those skilled in the art or described herein. In other embodiments, the oxidizable surface coating may interdiffuse into the titanium substrate during oxidation. The resulting oxide-interdiffused coated titanium substrate may have a grey to black surface color.

The oxidizable surface coating may be heat treated under a pressure controlled environment to interdiffuse into the titanium substrate using any suitable manner known in the art. For instance, the oxidizable surface coated titanium alloy substrate can be heat treated in a pressure controlled environment such as under a vacuum. In various aspects, the coating may be heat treated under vacuum at a temperature of at least about 100° C., at least about 200° C., less than about 300° C., between about 100° C. and about 300° C., between about 100° C. and about 200° C., etc. By way of example, the coating may be heat treated under vacuum for at least about 5 minutes, at least about 10 minutes, at least about 20 minutes, at least about 30 minutes, at least about 45 minutes, at least about 1 hour, etc. Further, the temperature and heat treatment time can vary. For example, the time can be shortened when the temperature increases and vice versa. Alternatively, the oxidizable surface coating may interdiffuse into the titanium substrate during oxidation.

The average thickness of the coating-interdiffused layer can be greater than 0.5 microns. In some variations, the average thickness of the coating-interdiffused layer is less than 1 micron. In other variations, the average thickness of the coating-interdiffused layer is less than 2 microns. In still other variations, the average thickness of the coating-interdiffused layer is less than 3 microns. In further variations, the average thickness of coating-interdiffused layer is less than 4 microns. In still further variations, the average thickness of the coating-interdiffused layer is less than 5 microns.

In embodiments having a coating-interdiffused layer, the coating-interdiffused layer may diffuse to a greater average thickness than is oxidized. In such cases, a portion of the coating-interdiffused layer can remain unoxidized (in addition to the oxide-interdiffused coating described above). In some variations, the average thickness of the interdiffused unoxidized layer can be at least 0.5 times the average thickness of the interdiffused oxidized coating. In other variations, the average thickness of the interdiffused unoxidized layer can be at least 1.0 times the average thickness of the interdiffused oxidized coating. In additional variations, the average thickness of the interdiffused unoxidized layer can be at least 1.5 times the average thickness of the interdiffused oxidized coating. In further variations, the average thickness of the interdiffused unoxidized layer can be at least 2.0 times the average thickness of the interdiffused oxidized coating. In still further variations, the average thickness of the interdiffused unoxidized layer can be at least 2.5 times the average thickness of the interdiffused oxidized coating.

Oxidation can be performed in any manner known in the art. In some aspects, the coated titanium surfaces can be oxidized by heating the surface to an elevated temperature for a period of time. In various aspects, the oxidation temperature can be at least about 300° C. In various aspects, the oxidation temperature can be at least about 350° C. In various aspects, the oxidation temperature can be at least about 400° C. In various aspects, the oxidation temperature can be at least about 450° C. In various aspects, the oxidation temperature can be at least about 500° C. In various aspects, the oxidation temperature can be at least about 550° C. In various aspects, the oxidation temperature can be at least about 600° C. In various aspects, the oxidation temperature can be at least about 700° C. By way of example, the oxidation temperature may be between about 300° C. and about 700° C., about 400° C. and about 700° C., about 500° C. and about 700° C., etc. However, the temperature may be higher under controlled atmospheric conditions. In various aspects, the oxidation time can be at least about 5 minutes, at least about 10 minutes, at least about 20 minutes, at least about 30 minutes, at least about 45 minutes, at least about 1 hour, at least about 2 hours, at least about 3 hours, at least about 4 hours, at least about 5 hours, up to about 20 hours, etc. In some aspects, the oxidation time can range from about 5 minutes to about 16 hours, from about 5 minutes to about 10 hours, from about 5 minutes to about 5 hours, from about 5 minutes to about 4 hours, from about 45 minutes to about 4 hours, etc. Further, the temperature and oxidation time can vary. For example, the oxidation time can be shortened when the temperature increases and vice versa.

As described herein, coated titanium substrate can be oxidized in a pressure controlled environment such as a vacuum chamber with a controlled partial pressure of oxygen. By controlling the partial pressure of oxygen, the color of the oxide can be tuned by controlling the oxygen content and/or stoichiometry of the surface oxide layer. Such methods may diminish the amount of nitrogen that can be absorbed in the substrate. Optionally, in addition to controlling the vacuum pressure, the amount of oxygen can be regulated by controlling the addition of nitrogen and/or argon.

In accordance with certain embodiments and without limiting the disclosure to a specific mechanism or mode of action, optical properties of oxidized zirconium surface coatings (whether or not diffused into an alloy substrate) can depend on the oxygen stoichiometry of the material. Black zirconia has been measured to have stoichiometry of ZrO_{1.96} (J. of the Am. Ceram. Soc., 51(6),1968), with the extra electrons maintaining charge neutrality. Zirconia is transparent in its single crystal form and white in the polycrystalline form. This is due to the large band gap and small population of defects (oxygen vacancies). Under reducing conditions where oxygen vacancies are created, polycrystalline zirconia blackens, indicating the presence of color or “F-centers” at localized positions within the alloy with energy levels lying within the band gap. Electrons are trapped within this band to maintain local charge neutrality.

Color is determined by the wavelength of light that is reflected or transmitted without being absorbed, assuming incident light is white light. The visual appearance of objects may vary with light reflection or transmission. In some embodiments, color may be quantified by parameters L*, a*, and b*, where L*stands for light brightness, a*stands for color between red and green, and b*stands for color between blue and yellow. For example, L*values less than 50 have a grey to black color, while L*near 0 suggest a dark color toward the black end of the spectrum.

For color measurement, testing equipment, such as X-Rite Color i7 XTH, X-Rite Coloreye 7000 may be used. These measurements are according to CIE/ISO standards for illuminants, observers, and the L*a*b*color scale. For example, the standards include: (a) ISO 11664-1:2007(E)/CIE S 014-1/E:2006: Joint ISO/CIE Standard: Colorimetry—Part 1: CIE Standard Colorimetric Observers; (b) ISO 11664-2:2007(E)/CIE S 014-2/E:2006: Joint ISO/CIE Standard: Colorimetry—Part 2: CIE Standard Illuminants for Colorimetry, (c) ISO 11664-3:2012(E)/CIE S 014-3/E:2011: Joint ISO/CIE Standard: Colorimetry—Part 3: CIE Tristimulus Values; and (d) ISO 11664-4:2008(E)/CIE S 014-4/E:2007: Joint ISO/CIE Standard: Colorimetry—Part 4: CIE 1976 L*a*b*Colour Space.

The oxidized coated titanium substrates or oxide-interdiffused titanium substrates disclosed herein have grey to black color. In some variations, the L*value of the alloys is from 0 to 50. In other variations, the L*value is less than 40. In some variations, the L*value is less than 30.

The oxidized coated titanium substrates or oxide-interdiffused titanium substrates disclosed herein have an a*from −10 to 10. In some variations, the oxidized coated titanium substrates or oxide-interdiffused titanium substrates have an a*from −5 to 5.

The oxidized coated titanium substrates or oxide-interdiffused titanium substrates disclosed herein have a b*from −20 to 5. In some variations, the oxidized coated titanium substrates or oxide-interdiffused titanium substrates have a b*from −15 to 5. In some variations, the oxidized coated titanium substrates or oxide-interdiffused titanium substrates have a b*from −10 to 5. The oxidized coated titanium substrates or oxide-interdiffused titanium substrates disclosed herein have a b*from −20 to 0. In some variations, the oxidized coated titanium substrates or oxide-interdiffused titanium substrates have a b*from −15 to 0. In some variations, the oxidized coated titanium substrates or oxide-interdiffused titanium substrates have a b*from −10 to 0.

In various embodiments, the color of the oxidized coated titanium substrate or oxide-interdiffused titanium substrate is uniform. In various aspects, such uniform color is the result of L*, a*, and b*values not varying by more than 5% at any two points on the oxidized coated titanium substrate or oxide-interdiffused titanium substrate. In other variations, L*, a*, and b*values not varying by more than 5% at any two points on the oxidized coated titanium substrate or oxide-interdiffused titanium substrate. In further variations, L*, a*, and b*values not varying by more than 4% at any two points on the oxidized coated titanium substrate or oxide-interdiffused titanium substrate. In still further variations, L*, a*, and b*values not varying by more than 3% at any two points on the oxidized coated titanium substrate or oxide-interdiffused titanium substrate. In additional variations, L*, a*, and b*values not varying by more than 2% at any two points on the oxidized coated titanium substrate or oxide-interdiffused titanium substrate. In still further additional variations, L*, a*, and b*values not varying by more than 1% at any two points on the oxidized coated titanium substrate or oxide-interdiffused titanium substrate.

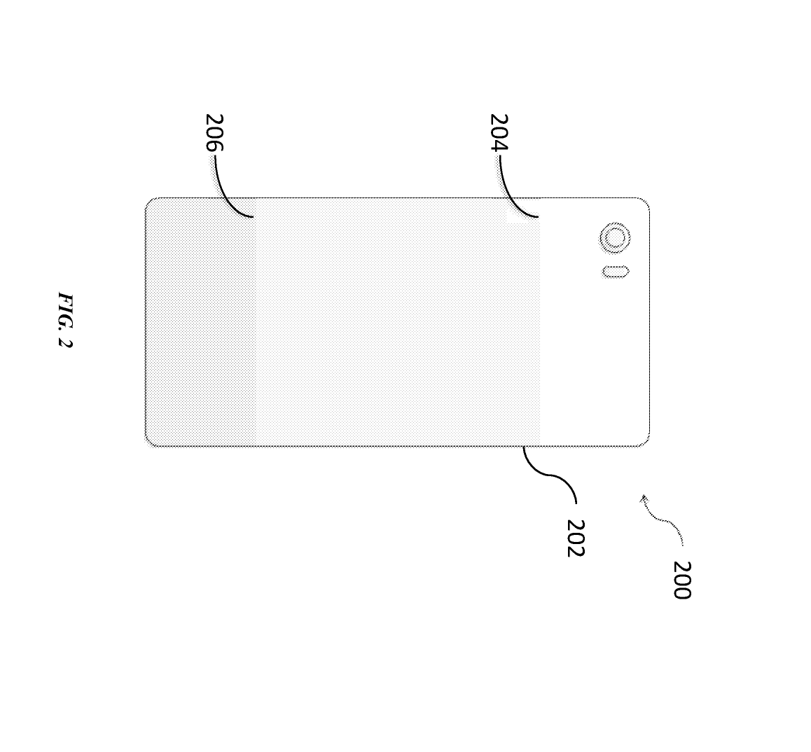

The darkened titanium alloys described herein can be used in a number of different uses. For example, the darkened titanium alloys can be used in the manufacture of an electronic device or a component thereof. FIG. 2 depicts a portable electronic device 200 having a micro-alloyed metallic glass coated metal substrate on a housing component 202. In the embodiment depicted in FIG. 2, the color of housing 202 changes between top portion 204 and bottom portion 206. As described herein, the bottom portion 206 of electronic device 200 appears as a darker color than top portion 204. As such, the surface of portable electronic device 200 can be controlled by the methods of the disclosure. FIG. 2 is not limiting. Housing component 202 can be altered in a similar fashion, in any manner described herein.

An electronic device herein can refer to any electronic device known in the art. For example, the electronic device can be a telephone, such as a cell phone, and a land-line phone, or any communication device, such as a smart phone, including, for example an iPhone®, and an electronic email sending/receiving device. It can be a part of a display, such as a digital display, a TV monitor, an electronic-book reader, a portable web-browser (e.g., iPad®), watch (e.g., AppleWatch), or a computer monitor. It can also be an entertainment device, including a portable DVD player, conventional DVD player, Blue-Ray disk player, video game console, music player, such as a portable music player (e.g., iPod®), or etc. It can also be a part of a device that provides control, such as controlling the streaming of images, videos, sounds (e.g., Apple TV®), or it can be a remote control for an electronic device. It can be a part of a computer or its accessories, such as the hard drive tower housing or casing, laptop housing, laptop keyboard, laptop track pad, desktop keyboard, mouse, and speaker. The article can also be applied to a device such as a watch or a clock.

The methods can also be valuable in forming wearable metallic glass products that have a good cosmetic profile and do not readily degrade or show evidence of wear.

Any ranges cited herein are inclusive. The terms “substantially” and “about” used throughout this Specification are used to describe and account for small fluctuations. For example, they can refer to less than or equal to.±5%, such as less than or equal to±2%, such as less than or equal to±1%, such as less than or equal to±0.5%, such as less than or equal to±0.2%, such as less than or equal to±0.1%, such as less than or equal to±0.05%.

Having described several embodiments, it will be recognized by those skilled in the art that various modifications, alternative constructions, and equivalents can be used without departing from the spirit of the invention. Additionally, a number of well-known processes and elements have not been described in order to avoid unnecessarily obscuring the present invention. Accordingly, the above description should not be taken as limiting the scope of the invention.

### EXAMPLES

The following examples illustrate various aspects of the disclosure. It will be apparent to those skilled in the art that many modifications, both to materials and methods, may be practiced without departing from the scope of the disclosure.

### Example 1

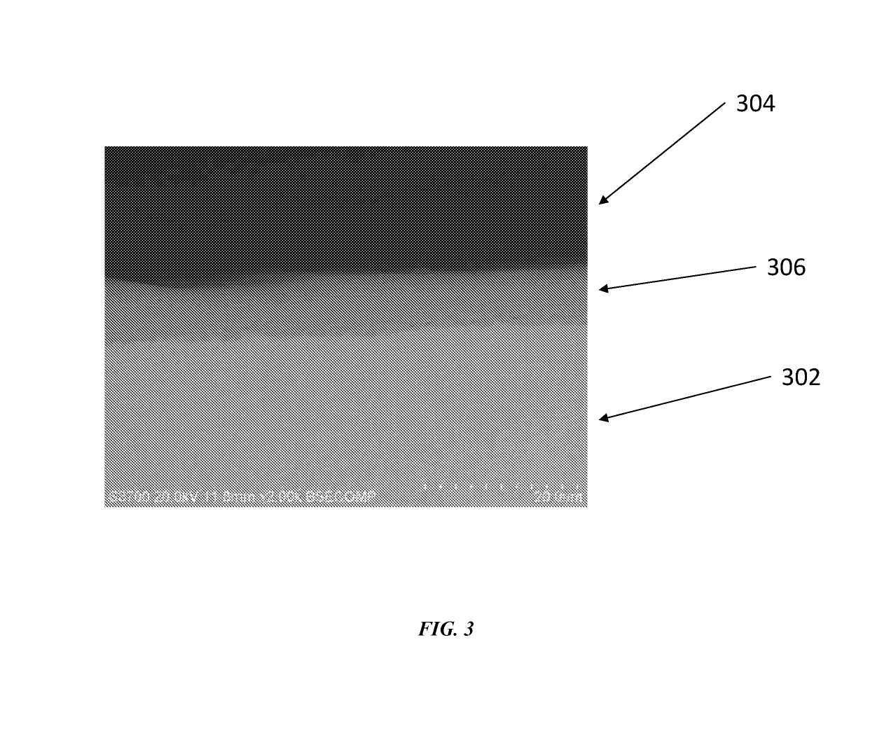

In this example, bulk Zr705 alloy (zirconium with 2-3% niobium content) was deposited by PVD as a surface coating onto a Ti-6Al-4V (an α+β titanium alloy, Grade 5, 6% aluminum, 4% vanadium) titanium substrate. The Zr705 alloy was heated at a temperature of 600° C. for four hours in air to oxidize the Zr705 surface coating. As shown in FIG. 3, the resulting oxidized titanium substrate 302 has a coating 304 with a dark surface color. The titanium alloy further includes an interdiffused portion 306 in which Zr705 has diffused into the Ti-6Al-4V substrate.

### Example 2

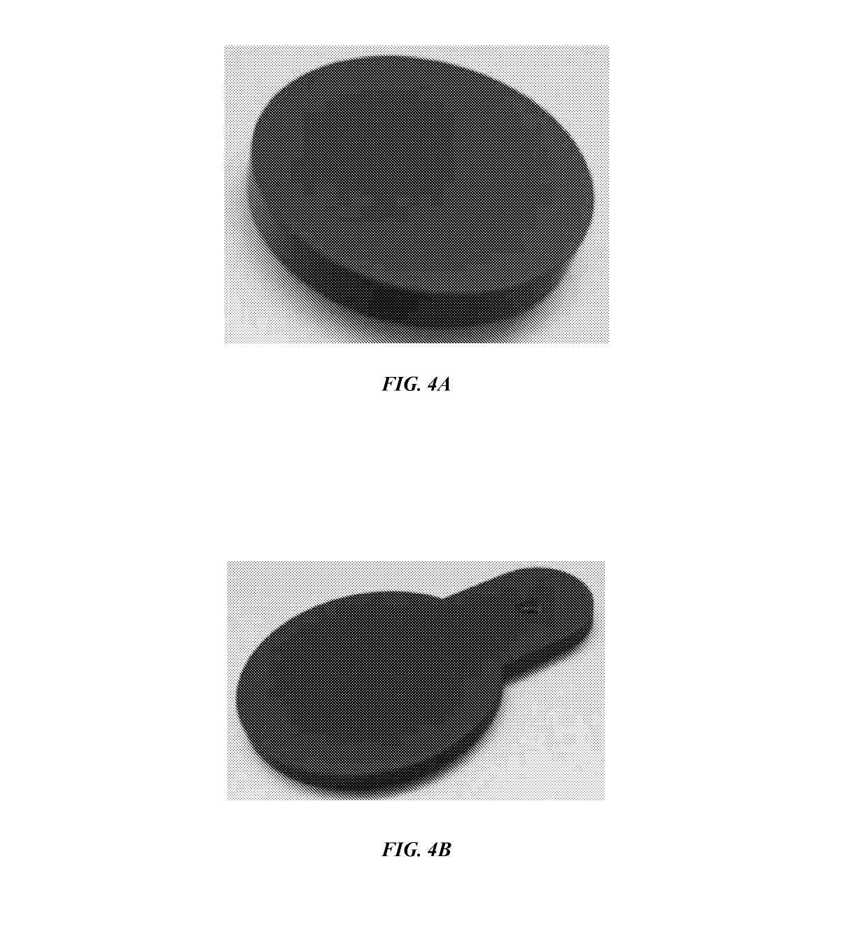

In this example, nominally pure Zr was deposited by PVD as a surface coating onto the surface of two titanium alloy substrates: FIG. 4A depicts Zr deposited on the surface of Ti-6Al-4V (an α+β titanium alloy, Grade 5), and FIG. 4B depicts Zr deposited on the surface of Ti-15V-3Al-3Cr-3Sn (a β titanium alloy, AMS 4914). The oxidized coated titanium surface was heated at a temperature of 600° C. for four hours in air to oxidize the Zr surface coating. FIG. 4A depicts the darkened Ti-6Al-4V alloy. FIG. 4B depicts darkened Ti-15V-3Al-3Cr-3Sn substrate.

### Example 3

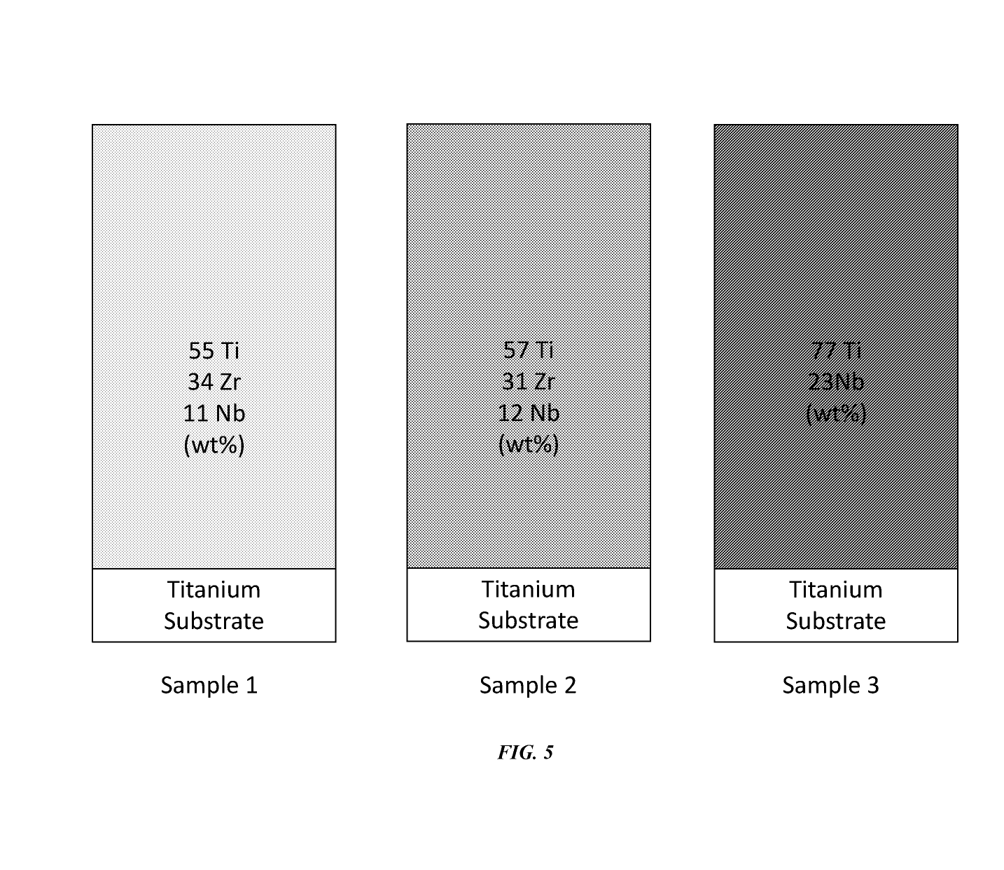

In this example, three different Zr-containing surface coatings (oxidizable surface coatings 1, 2, and 3) are deposited by PVD on the surface of a titanium substrate. The oxidizable coatings are deposited by PVD to a thickness of approximately 3 microns (Sample 1: 55/34/11 TI/Zr/Nb (wt %); Sample 2: 57/31/12 Ti/Zr/Nb (wt %); Sample 3: 77/23 Zr/Nb (wt %)). For Samples 1 and 2, the oxidized coated titanium surface is heated at a temperature of 600° C. for four hours in air to oxidize the surface coating. For Sample 3, the coated titanium alloy is heat treated under vacuum to interdiffuse the coating into the titanium substrate. The oxide-interdiffused titanium substrate of Sample 3 is then heat treated in air. As shown in FIG. 5, Sample 1 has a light grey surface color; Sample 2 has a darker grey surface color; while Sample 3 has a dark grey surface color.

### Example 4

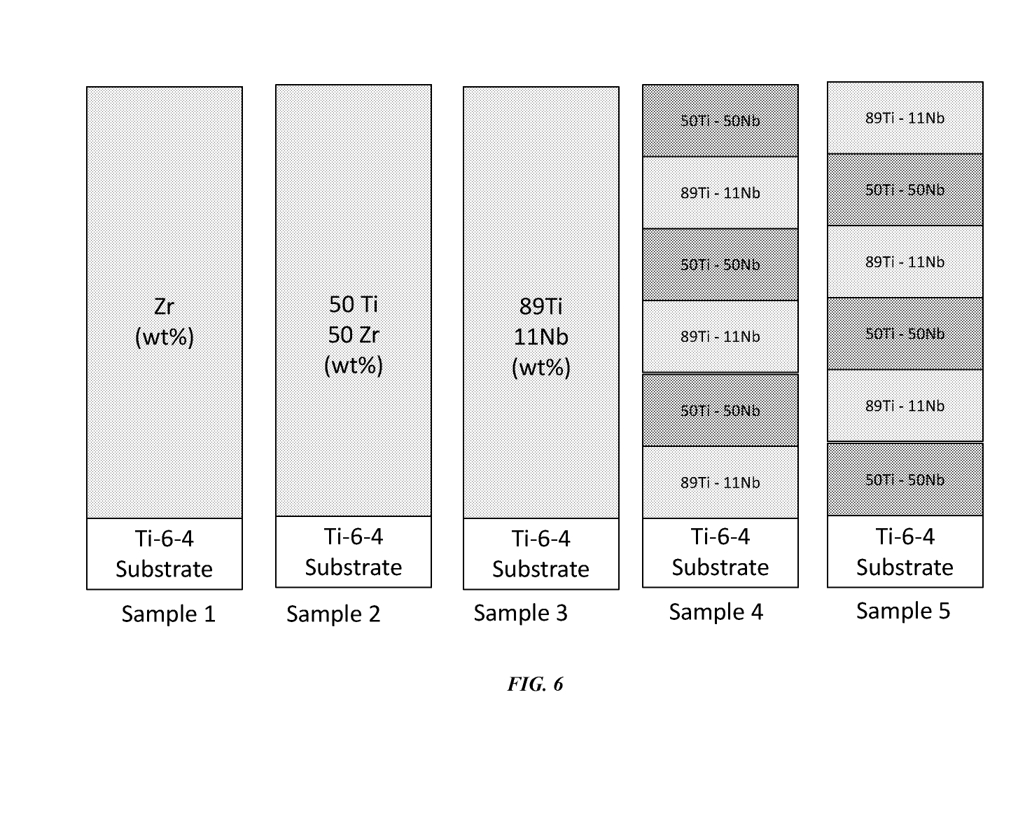

In this example, five samples (Samples 1-5) of a titanium substrate Ti-6-4 coated with five different oxidizable surface coatings were produced. Each coating was deposited on the titanium substrate to a total thickness of approximately 3 microns by PVD under inert gas. Sample 1: nominally pure Zr; Sample 2: 50/50 Ti/Zr (wt %); Sample 3: 89/11 Ti/Nb (wt %). Samples 4 and 5 were prepared as layers of differing oxidizable surface coatings. Samples 4 and 5 are comprised of alternating layers of 50/50 Ti/Zr (wt %) and 89/11 Ti/Nb, as illustrated in FIG. 6.

The coated alloys were heat treated under vacuum to interdiffuse each oxidizable surface coating into the titanium substrate. The oxide-interdiffused titanium substrates were then heat treated to oxidize the alloys and form a darkened color.

The coated alloys were treated at different temperatures and oxidation times. The different treatment resulted in oxidized coated alloys that varied in color and uniformity. Samples 2 and 4 provided consistent darkening at a darker hue after heat treatment at 600° C. for 3 hours. Samples 2 and 4 provided slightly better hue after heat treatment at 500° C. for 16 hours. For each of the alloys, L*lower than 50, a*was from 10 to −10, and a b*was from −20 to 0.

### Example 5

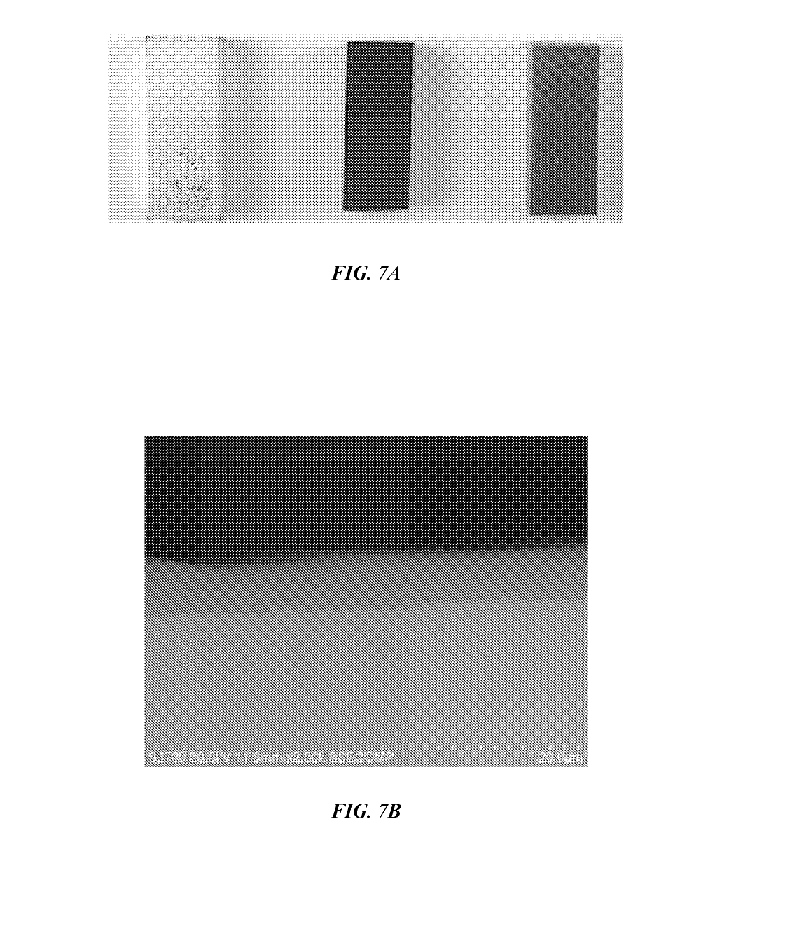

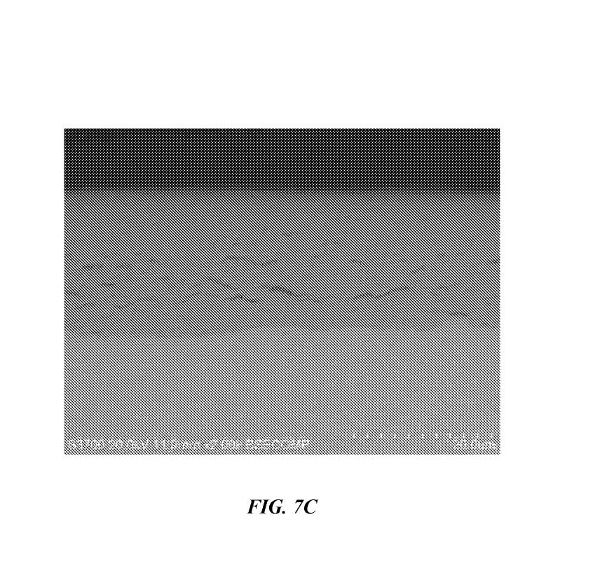

In this example, a bulk Zr705 alloy (zirconium with 2-3% niobium content) was oxidized in air for four hours at 600° C., 700° C., and 800° C. In accordance with the methods of the disclosure, a composition similar to the bulk Zr705 alloy can be deposited onto a titanium substrate and oxidized to form a dark surface, as illustrated herein. For instance, as shown in FIG. 7A, the Zr705 oxidized surface at 600° C., 700° C., and 800° C., respectively, is illustrated. As shown, at 600° C. the surface coating oxidized more uniformly than at 700° C. Further, as shown in FIGS. 7B and 7C, the cross-section of the surface coated titanium substrate oxidized to a greater depth than the surface coated titanium substrate oxidized when heat treated at 600° C. (FIG. 7B) than when heat treated at 700° C. (FIG. 7C). In various instances, the uniform color is the result of oxidation deeper in the average thickness of the oxidized surface coating.

### Example 6

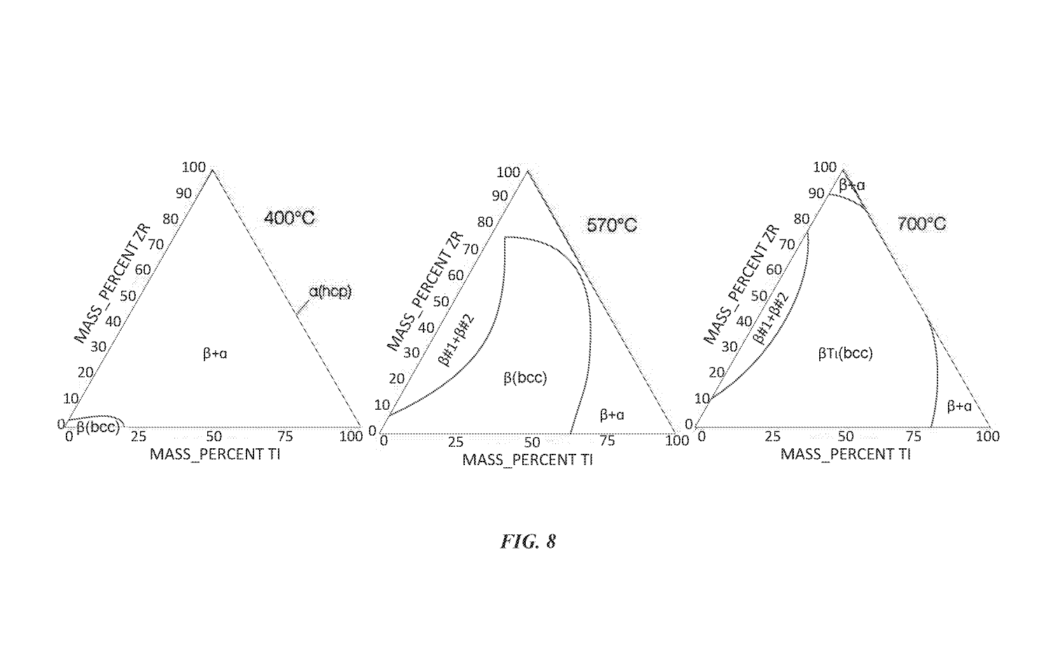

In this example, selection of alloy components of exemplary oxidizable surface coatings is illustrated. The relative percentage of alloy components can be selected by determining the thermodynamically stable phase for the alloy components. FIG. 8 depicts three calculated diagrams of the Nb-Ti-Zr system at 400° C., 570° C., and 700° C. using the thermodynamics description of Tokunaga et al., which are in agreement with the experimentally determined. Once the ternary alloy is selected, additional optional elements such as vanadium, hafnium, chromium, tantalum, and/or molybdenum can be added.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not target to be exhaustive or to limit the embodiments to the precise forms disclosed. It will be apparent to one of ordinary skill in the art that many modifications and variations are possible in view of the above teachings.

We claim:

1. A titanium alloy comprising:
a titanium substrate, and
an oxidized surface coating disposed on the titanium substrate;
said oxidized surface coating having a dark color.

2. The titanium alloy of claim 1, wherein the oxidized surface coating has an average thickness of at least 1 micron.

3. The titanium alloy of claim 2, wherein the oxidized surface coating has an average thickness of at least 2 micron.

4. The titanium alloy of claim 1, wherein the oxidized surface coating is interdiffused into the titanium substrate.

5. The titanium alloy of claim 4, further comprising an unoxidized interdiffused layer comprising zirconium.

6. The titanium alloy of claim 5, wherein the average thickness of the interdiffused unoxidized coating is at least 0.5 times the average thickness of the interdiffused oxidized coating.

7. The titanium alloy of claim 1, wherein the oxidized surface coating comprises unalloyed zirconium, a zirconium alloy, or combinations thereof.

8. The titanium alloy of claim 1, wherein the oxidized surface coating comprises zirconium alloyed with titanium, niobium, or titanium and niobium.

9. The titanium alloy of claim 1, wherein the titanium substrate comprises a near-α titanium alloy, an α+β titanium alloy or a β-titanium alloy.

10. The titanium alloy of claim 9, wherein the titanium substrate comprises Ti 6Al-4V or Ti-15V-3-3-3.

11. A method of creating a dark surface on a titanium substrate comprising:
depositing an oxidizable surface coating on the titanium substrate to form a coated titanium substrate; and
oxidizing the surface of the coated titanium substrate to form an oxidized coated titanium substrate having a dark surface color.

12. The method of claim 11, wherein the oxidizable surface coating is deposited using physical vapor deposition (PVD).

13. The method of claim 11, wherein the oxidizable surface coating is deposited to an average thickness of at least 2 microns.

14. The method of claim 13, wherein the oxidizable surface coating is deposited to an average thickness of at least 3 microns.

15. The method of claim 11, wherein the surface of the coated titanium substrate is oxidized by heat treatment.

16. The method of claim 15, wherein the heat treatment is performed at a temperature of between about 300° C. and about 700° C.

17. The method of claim 15, wherein the heat treatment is performed for about 5 minutes to about 16 hours.

18. The method of claim 11, wherein the oxidizable surface coating is interdiffused into the titanium substrate during oxidation.

19. A method of creating a dark surface color on a titanium substrate comprising:
depositing an oxidizable surface coating on a titanium substrate;
interdiffusing the oxidizable surface coating into the titanium substrate to form a coating-interdiffused titanium alloy; and
oxidizing the coating-interdiffused titanium alloy to form an oxide-interdiffused titanium alloy having a dark surface color.

20. The method of claim 19, wherein the coating-interdiffused titanium alloy is partially oxidized to thereby form an interdiffused unoxidized layer and an interdiffused oxidized coating.
